(19) United States
(12) Patent Application Publication
(10) Pub. No.: US 2024/0196668 A1
(43) Pub. Date: Jun. 13, 2024

(54) ORGANIC LIGHT EMITTING DISPLAY APPARATUS

(71) Applicant: LG Display Co., Ltd., Seoul (KR)

(72) Inventor: HyunHaeng LEE, Paju-si (KR)

(73) Assignee: LG Display Co., Ltd., Seoul (KR)

(21) Appl. No.: 18/524,805

(22) Filed: Nov. 30, 2023

(30) Foreign Application Priority Data
Dec. 8, 2022 (KR) 10-2022-0170408

(51) Int. Cl. H10K 59/124; H10K 59/122; H10K 59/38; H10K 59/80

(52) U.S. Cl. CPC H10K 59/124; H10K 59/122; H10K 59/38; H10K 59/879; H10K 59/8791; H10K 59/8792

(57) ABSTRACT

An organic light emitting display apparatus includes a plurality of subpixels in an emission region; and a planarization layer in the plurality of subpixels, the planarization layer including a plurality of light extraction patterns including a convex portion and a plurality of concave portions. At least a first light extraction pattern of the plurality of light extraction patterns is rotated with respect to a center portion of each of the plurality of concave portions.

### CROSS-REFERENCE TO RELATED APPLICATIONS

This application claims the benefit of the Korean Patent Application No. 10-2022-0170408 filed on Dec. 8, 2022, which is hereby incorporated by reference as if fully set forth herein.

### BACKGROUND

### Technical Field

The present disclosure relates to an organic light emitting display apparatus, and more particularly, to an organic light emitting display apparatus that may increase internal light extraction efficiency and may decrease a reflectance based on external light.

### Discussion of the Related Art

As society advances to an information-oriented society, interest in display apparatuses for displaying an image and the needs for using such display apparatuses are variously increasing. Thus, the display technology field has rapidly advanced. Therefore, various lightweight and thin flat display apparatuses have been developed, which have attracted much attention. Recently, display apparatuses, such as liquid crystal display (LCD) apparatuses and organic light emitting display apparatuses, are being used.

Organic light emitting display apparatuses are light self-emitting display apparatuses that display an image on a display panel through emitting of light from an organic emission layer disposed between two electrodes. Thus, organic light emitting display apparatuses do not need a separate light source such as a backlight unit unlike LCD apparatuses. Further, organic light emitting display apparatuses may be manufactured to be lightweight and thin. Also, organic light emitting display apparatuses are efficient in terms of power consumption by low voltage driving and have good in color implementation, response time, viewing angle, and contrast ratio. As a result, organic light emitting display apparatuses are attracting much attention as next-generation display apparatuses.

In organic light emitting display apparatuses, an image is displayed as internal light is discharged to the outside of a display apparatus. Research for increasing internal light efficiency is continuously performed, and research for improving a reflectance based on external light is being performed.

### SUMMARY

Accordingly, embodiments of the present disclosure are directed to providing an organic light emitting display apparatus that substantially obviates one or more problems due to limitations and disadvantages of the related art.

An aspect of the present disclosure is to provide an organic light emitting display apparatus in which light emitted from an emission layer of the organic light emitting display apparatus is discharged to the outside, and thus, the light extraction efficiency of the emitted light may be enhanced in displaying an image.

Another aspect of the present disclosure is to provide an organic light emitting display apparatus which may minimize light, which is again output as external light is incident and is reflected from the inside, or light which is again output as a reflectance is increased by a reflection electrode, and thus, may improve black color (or black rising) or reflection visibility based on reflection of external light and may minimize or reduce the occurrence of rainbow Mura and a pearl phenomenon.

Another aspect of the present disclosure is to provide an organic light emitting display apparatus which may minimize or reduce the occurrence of a ring stain or/and a pearl stain caused by scattering of light incident from the outside or/and light occurring in the organic light emitting display apparatus.

Another aspect of the present disclosure is to provide an organic light emitting display apparatus which may enhance an aperture ratio of the organic light emitting display apparatus and may minimize or reduce a color paleness phenomenon caused by various scattered light occurring therein.

Another aspect of the present disclosure is directed to providing an organic light emitting display apparatus that may enhance the light extraction efficiency of the organic light emitting display apparatus, implement high efficiency and high luminance, extend a lifetime of the organic light emitting display apparatus, and decrease power consumption, thereby implementing low power.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described, a light emitting display apparatus comprises a plurality of subpixels in an emission region; and a planarization layer in the plurality of subpixels, the planarization layer including a plurality of light extraction patterns including a convex portion and a plurality of concave portions, wherein at least a first light extraction pattern of the plurality of light extraction patterns is rotated with respect to a center portion of each of the plurality of concave portions.

In another aspect, an organic light emitting display apparatus comprises a substrate having edges defined parallel to a first direction and a second direction; a plurality of subpixels in an emission region defined on the substrate; and a planarization layer in the plurality of subpixels, the planarization layer including a plurality of light extraction patterns including a plurality of concave portions in each subpixel, wherein each one of the light extraction patterns has a shape defining one or more symmetry axis, the one or more symmetry axis being rotated with respect to the first and second directions to define an angle with respect to the first and second directions.

In another aspect, an organic light emitting display apparatus comprises a substrate having a plurality of subpixels defined in an emission region of the substrate; a planarization layer on the substrate in the plurality of subpixels, the planarization layer having an upper surface including a plurality of concave portions in each subpixel, and a light emitting device in each of the plurality of plurality of subpixels, each light emitting device being on the concave portions of the respective subpixel and having a shape conforming to the respective concave portions.

In another aspect, an organic light emitting display apparatus comprises a plurality of subpixels including an emission region; and a planarization layer disposed in the plurality of subpixels, the planarization layer including a plurality of light extraction patterns including a convex portion and a plurality of concave portions, wherein a light extraction pattern disposed in at least one of the plurality of subpixels is oriented at an angle about a center portion of each of the plurality of concave portions.

According to an embodiment of the present disclosure, the orientation of a light extraction pattern disposed in each of the plurality of subpixels differs for each of the plurality of subpixels.

According to an embodiment of the present disclosure, orientations of light extraction patterns disposed in two adjacent subpixels of the plurality of subpixels differ by three or more-degrees and are within a range of more than 0 degrees and less than 60 degrees.

According to an embodiment of the present disclosure, orientations of light extraction patterns disposed in subpixels of the same color among light extraction patterns respectively disposed in the plurality of subpixels differ by three or more-degrees and are within a range of more than 0 degrees and less than 60 degrees.

According to an embodiment of the present disclosure, orientations of light extraction patterns disposed in two subpixels adjacent to each other in a first direction, a second direction perpendicular to the first direction, or a diagonal direction among the plurality of subpixels differ by three or more-degrees and are within a range of more than 0 degrees and less than 60 degrees.

An organic light emitting display apparatus according to the present disclosure may implement high efficiency and high luminance, and thus, may extend a lifetime of an organic light emitting device and may decrease power consumption, thereby implementing low power.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principle of the disclosure. In the drawings:

FIG. 1 is a diagram for describing an organic light emitting display apparatus according to an example embodiment of the present disclosure;

FIG. 2 is a cross-sectional view illustrating one subpixel SP illustrated in FIG. 1;

FIG. 3 is a diagram illustrating a plane structure of one pixel P illustrated in FIG. 1;

FIG. 4 is a plan view illustrating an enlarged region A of FIG. 3 according to an example embodiment;

FIG. 5 is a diagram illustrating a plurality of pixel blocks provided in an organic light emitting display apparatus according to an example embodiment of the present disclosure;

FIG. 6 is a diagram illustrating a rotation structure of a pixel group-based light extraction pattern disposed in one pixel block illustrated in FIG. 5;

FIG. 7A is a diagram illustrating the enlargement of a light extraction pattern provided in a pixel group of 1^{st} row, j^{th} column illustrated in FIG. 6;

FIG. 7B is a diagram illustrating the enlargement of a light extraction pattern provided in a pixel group of 2^{nd} row, j^{th} column illustrated in FIG. 6;

FIG. 8A is a diagram illustrating a plurality of pixel blocks provided in an organic light emitting display apparatus according to another example embodiment of the present disclosure;

FIG. 8B is a diagram illustrating a rotation structure of a pixel group-based light extraction pattern disposed in one pixel block illustrated in FIG. 8A;

FIG. 9 is a diagram illustrating a rotation structure of a pixels-based light extraction pattern provided in an organic light emitting display apparatus according to another example embodiment of the present disclosure;

FIG. 10 is a diagram illustrating a rotation structure of a subpixels-based light extraction pattern provided in an organic light emitting display apparatus according to another example embodiment of the present disclosure;

FIG. 11 is a diagram illustrating one pixel in an organic light emitting display apparatus according to another example embodiment of the present disclosure;

FIG. 12 is a diagram illustrating a rotation structure of a subpixels-based light extraction pattern provided in the organic light emitting display apparatus of FIG. 11;

FIG. 13 is a cross-sectional view taken along line I-I′ illustrated in FIG. 11;

FIG. 14 is a cross-sectional view taken along line II-II′ illustrated in FIG. 11;

FIG. 15 is a diagram for describing reflected light occurring in a display apparatus;

FIG. 16A is a photograph showing a color paleness phenomenon;

FIG. 16B is a photograph showing an improved effect of an organic light emitting display apparatus according to another example embodiment of the present disclosure;

FIG. 17A is a photograph showing rainbow Mura with respect to external reflected light in a display apparatus;

FIG. 17B is a photograph showing a pearl phenomenon; and

FIG. 17C is a photograph showing an effect where rainbow Mura and a pearl phenomenon are reduced in an organic light emitting display apparatus according to another example embodiment of the present disclosure.

### DETAILED DESCRIPTION

Hereinafter, embodiments of the present disclosure will be described in detail with reference to the drawings. The embodiments introduced below are provided as examples so that the spirit of the present invention can be sufficiently conveyed to those skilled in the art. Accordingly, the present disclosure is not limited to the embodiments described below and may be embodied in other shapes.

In the drawings, a size and a thickness of the device may be exaggerated for convenience. For convenience of description, a scale of each of elements shown in the accompanying drawings differs from a real scale, and thus, is not limited to a scale shown in the drawings. Like reference numerals refer to like elements throughout.

Further, in the following description, when the detailed description of the relevant known technology is determined to unnecessarily obscure the important point of the present disclosure, the detailed description will be omitted.

In a case where “comprise,” “have,” and “include” described in the present specification are used, another part may be added unless “only” is used. The terms of a singular form may include plural forms unless referred to the contrary.

Spatially relative terms, such as “below,” “beneath,” “lower,” “above,” “upper,” and the like, may be used to easily describe the relationship of one element or elements and another element or elements as illustrated in the drawings. Spatially relative terms may be understood as terms including different directions of the device in use or operation, in addition to the direction illustrated in the drawings. For example, when the device in the drawings is turned over, elements described as “below” or “beneath” of other elements may be placed “above” of other elements. Thus, the exemplary term “below” or “beneath” may include both a downward direction and an upward direction.

In describing elements of the present disclosure, the terms “first,” “second,” “A,” “B,” “(a),” “(b),” etc. may be used. These terms are intended to identify the corresponding elements from the other elements, and basis, order, sequence, or number of the corresponding elements should not limit by these terms.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in co-dependent relationship.

Hereinafter, embodiments of the present disclosure will be described in detail with reference to the accompanying drawings.

FIG. 1 is a diagram for describing an organic light emitting display apparatus according to an example embodiment of the present disclosure.

With reference to FIG. 1, an organic light emitting display apparatus may include a display panel 10 including a substrate 100 and an opposite substrate 300 that are bonded to each other. The substrate 100 includes a thin film transistor, and the substrate 100 may be a transparent glass substrate or a transparent plastic substrate. The substrate 100 may include a display area AA and a non-display area IA.

The display area AA is an area for displaying an image, the display area AA may be a pixel array area, an active area, a pixel array portion, a display portion, or a screen. The display area AA may include a plurality of pixels P. The plurality of pixels P may each be defined as a unit area from which light is actually emitted. The pixels P may include a plurality of subpixels SP. According to an example embodiment, each of the plurality of pixels P may include at least one red subpixel, at least one green subpixel, at least one blue subpixel, and at least one white subpixel.

The non-display area IA may be an area in which an image is not displayed, the non-display area IA may be a peripheral circuit area, a signal supply area, a non-active area, or a bezel area. The non-display area IA may be configured to surround the display area AA. The display panel 10 or the substrate 100 may further include a peripheral circuit unit 120 disposed in the non-display area IA. The peripheral circuit unit 120 may include a gate driving circuit connected with a plurality of pixels P.

The opposite substrate 300 may be disposed to be opposite-bonded to the substrate 100 by an adhesive member (or a transparent adhesive), or may be provided as a type where an organic material or an inorganic material is stacked on the substrate 100. The opposite substrate 300 may be an upper substrate, a second substrate, or an encapsulation substrate and may encapsulate the substrate 100.

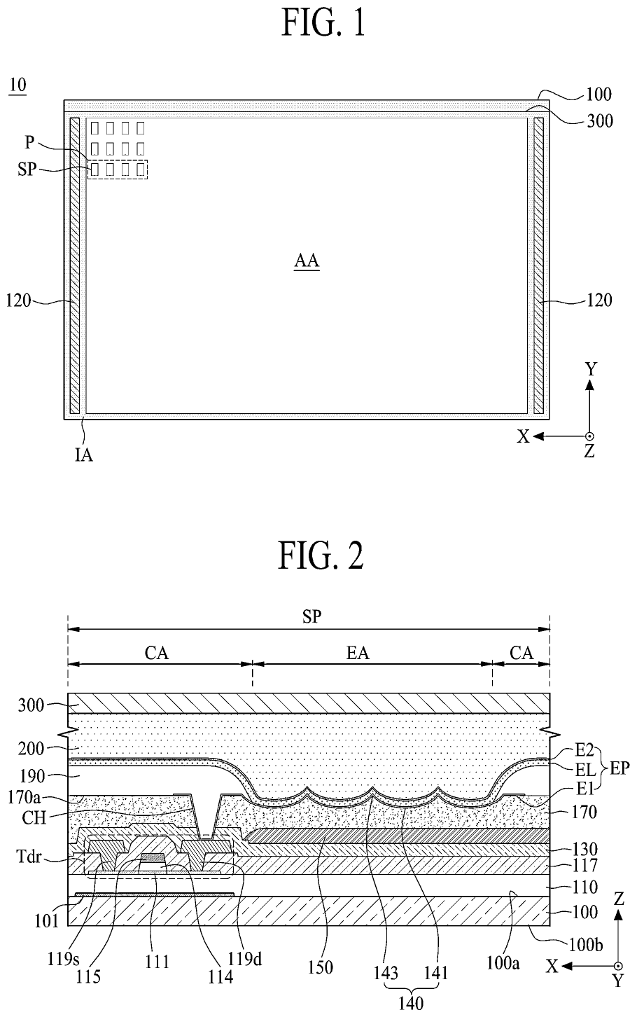

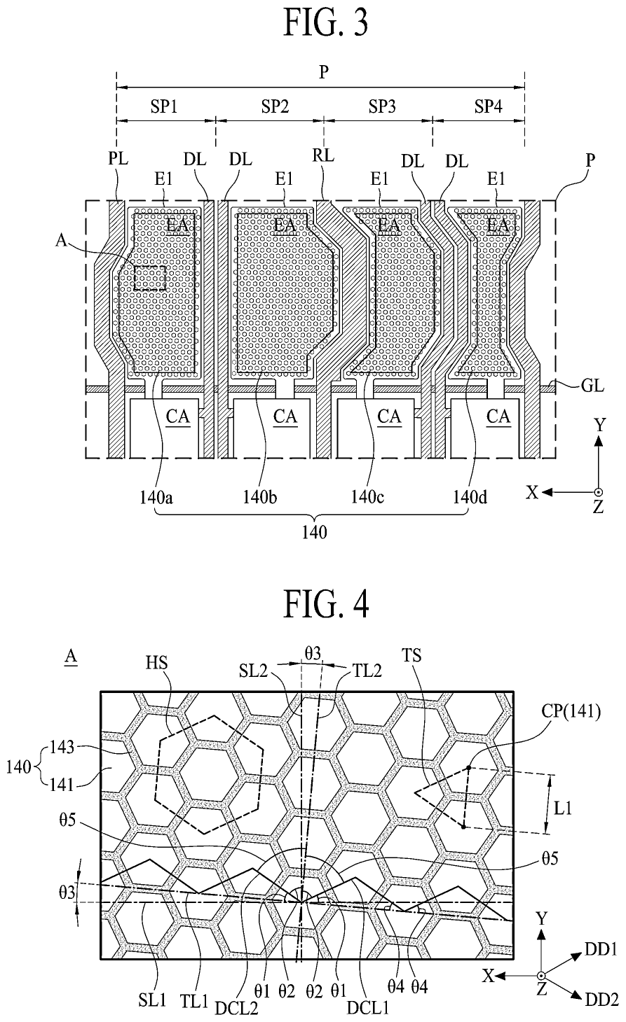

FIG. 2 is a cross-sectional view illustrating a cross-sectional structure of one subpixel SP according to an example embodiment of the present disclosure. FIG. 3 is a diagram illustrating a plane structure of one pixel P illustrated in FIG. 1, and FIG. 4 is a plan view illustrating an enlarged region A of FIG. 3 according to an example embodiment.

In FIGS. 2 to 4, an organic light emitting display apparatus may include a plurality of pixels P where one pixel P is configured with a plurality of subpixels SP at the display area AA. The one pixel P may include a plurality of subpixels SP1, SP2, SP3, and SP4, and each of the plurality of subpixels SP may include a plurality of the light extraction patterns 140 (140a, 140b, 140c, and 140d) in an emission region EA defined by a bank layer 190.

According to an example embodiment, the light extraction pattern 140 disposed in at least one subpixel of the plurality of subpixels SP1, SP2, SP3, and SP4 may have a structure that is rotated with respect to a reference point (or an arbitrary point) of the emission region EA. For example, the light extraction pattern 140 disposed in at least one subpixel of the plurality of subpixels SP1, SP2, SP3, and SP4 may have a structure which has rotated with respect to a center portion CP of each of a plurality of concave portions 141. For example, each of first to fourth light extraction patterns 140a, 140b, 140c, and 140d may be rotated or reversely rotated by different angles with respect to a reference point of a corresponding emission region EA or a center portion CP of one concave portion 141. Accordingly, the light extraction pattern 140 configured at each of the subpixels SP1, SP2, SP3, and SP4 of each of the plurality of pixels P may be rotated or reversely rotated by different angles.

An outermost pattern of the plurality of the light extraction patterns 140a, 140b, 140c, and 140d may be disposed up to the outside of the emission region EA.

The plurality of subpixels SP1, SP2, SP3, and SP4 may include a first subpixel SP1, a second subpixel SP2, a third subpixel SP3, and a fourth subpixel SP4, which emit lights of different colors. The first subpixel SP1 may be a red subpixel, the second subpixel SP2 may be a white subpixel, the third subpixel SP3 may be a blue subpixel, and the fourth subpixel SP4 may be a green subpixel. The emission areas EA of each of the first to fourth subpixels SP1, SP2, SP3, and SP4 may have different sizes (or areas) from each other.

The one subpixel SP may include an emission region EA and a circuit region CA. The circuit region CA may be spatially separated from the emission region EA, in the subpixel SP. The emission region EA may be a region which is defined as a first electrode E1 is opened by the bank layer 190, in the subpixel SP. The first electrode E1 may be an electrode which functions as a pixel electrode or an anode electrode. The circuit region CA may be a non-emission region or a non-opening region.

A gate line GL may be disposed to cross and extend between the emission region EA and the circuit region CA of the subpixel SP. A plurality of data lines DL or a reference line RL may be disposed to cross and extend between an emission region EA and adjacent emission region EA or between a circuit region CA and adjacent circuit region CA, between two adjacent subpixels SP of the plurality of subpixels SP. The reference line RL may be used as a sensing line for externally sensing a variation in characteristics of a driving thin film transistor disposed in the circuit region CA of the pixel P and/or a variation in characteristics of a light emitting device layer disposed at the circuit region CA in a sensing driving mode of the pixel P.

The organic light emitting display apparatus according to the present disclosure may include a buffer layer 110, a driving thin film transistor (TFT) Tdr, a protection layer 130, a planarization layer 170, and a light emitting device EP, which are stacked on a first surface 100a of the substrate 100. An optical film (not shown) may be disposed at a second surface 100b of the substrate 100. An image may be displayed in a direction toward the second surface 100b of the substrate 100. For example, the substrate 100 may be disposed in a direction in which light emitted from the light emitting device EP is irradiated.

The buffer layer 110 disposed at the first surface 100a of the substrate 100 may be disposed all over the first surface 100a of the substrate 100. The buffer layer 110 may prevent or at least reduce materials contained in the substrate 100 from spreading to a transistor layer during a high-temperature process in the manufacturing of the thin film transistor, or may prevent external water or moisture from permeating into the light emitting device. Optionally, depending on the case, the buffer layer 110 may be configured with a plurality of layers, or may be omitted.

The driving TFT Tdr may be disposed in the circuit region CA, and the driving TFT Tdr may include an active layer 111, a gate insulation layer 114, a gate electrode 115, an interlayer insulation layer 117, a drain electrode 119d, and a source electrode 119s. The drain electrode 119d and the source electrode 119s may be switched and defined based on the type of the driving TFT Tdr.

The active layer 111 configuring the driving TFT Tdr may be configured with a semiconductor material based on any one of amorphous silicon, polycrystalline silicon, oxide, and organic materials.

The gate insulation layer 114 may be formed in an island shape and only over the channel region of the active layer 111, or may be formed over an entire front surface of the buffer layer 110 or substrate 100 including the active layer 111.

The interlayer insulation layer 117 may be disposed over the gate electrode 115 and the active layer 111. The interlayer insulation layer 117 may be disposed all over the circuit region CA and the emission region EA. The interlayer insulation layer 117 may include an inorganic material or an organic material, or may include a combination thereof.

A switching TFT and a capacitor may be further disposed in the circuit region CA along with the driving TFT Tdr. A light blocking layer 101 may be further disposed under an active layer 111 of at least one of the driving TFT Tdr and the switching TFT on the substrate 100.

The protection layer 130 may be provided on the substrate 100 to cover the driving TFT Tdr. The protection layer 130 may be configured to cover the drain electrode 119d and the source electrode 119s of the driving TFT Tdr and the interlayer insulation layer 117. The protection layer 130 may be disposed all over the circuit region CA and the emission region EA. The protection layer 130 may be referred to as a passivation layer.

The organic light emitting display apparatus according to the present disclosure may further include a color filter layer 150 that is on the first surface 100a of the substrate 100. The color filter layer 150 may be disposed between the substrate 100 and the planarization layer 170 to overlap at least one emission region EA. The color filter layer 150 according to another example embodiment may be disposed between the interlayer insulation layer 117 and the protection layer 130 to overlap with the emission region EA, or may be disposed between the substrate 100 and the interlayer insulation layer 117.

The color filter layer 150 may have a larger size than the emission region EA. The color filter layer 150 may be wider than the emission region EA, and thus, may be disposed in a region which is wider than a region, where the plurality of the light extraction patterns 140 are disposed, of the planarization layer 170. When the color filter layer 150 has a size which is greater than that of the light extraction pattern 140, the occurrence of light leakage where internal light is leaked to an adjacent subpixel SP may be reduced.

The color filter layer 150 may transmit a wavelength of red, green, or blue, based on a color which is to be implemented by each subpixel SP. In the organic light emitting display apparatus according to the present disclosure, when one pixel P is configured with a first subpixel SP1, a second subpixel SP2, a third subpixel SP3 and a fourth subpixel SP4, a color filter layer 150 provided in the first subpixel SP1 may include a red color filter, the color filter layer 150 may not be disposed in the second subpixel SP2, a color filter layer 150 provided in the third subpixel SP3 may include a blue color filter, and a color filter layer 150 provided in the fourth subpixel SP4 may include a green color filter.

The planarization layer 170 may be provided on the substrate 100 to cover the protection layer 130. When the protection layer 130 is omitted, the planarization layer 170 may be provided on the substrate 100 to cover the driving TFT Tdr, the color filter layer 150, and several lines. The planarization layer 170 may be disposed all over the circuit region CA and the emission region EA. The planarization layer 170 may be disposed up to the non-display area to have a size which is relatively greater than that of the display area AA.

The planarization layer 170 may be disposed to have a thickness which is relatively thicker than another insulation layer and may provide a flat surface on the display area AA. The planarization layer 170 may be formed of an organic material such as photo acrylic, benzocyclobutene, polyimide, and fluorine resin, or the like.

The planarization layer 170 may include a plurality of the light extraction patterns 140 which are disposed in the emission region EA. The light extraction pattern 140 may be disposed at an upper surface 170a of the planarization layer 170 to overlap the emission region EA. The light extraction pattern 140 may also be disposed outside the emission region EA. The light extraction pattern 140 may be formed at the planarization layer 170 of the emission region EA to have a curved shape (or an uneven shape), whereby a traveling path of light emitted from the light emitting device EP is changed to increase light extraction efficiency of the pixel P. The light extraction pattern 140 may be a micro lens array.

The light extraction pattern 140 may include a first light extraction pattern 140a disposed in the first subpixel SP1 of the pixel P, a second light extraction pattern 140b disposed in the second subpixel SP2 of the pixel P, a third light extraction pattern 140c disposed in the third subpixel SP3 of the pixel P, and a fourth light extraction pattern 140d disposed in the fourth subpixel SP4 of the pixel P.

The light extraction pattern 140 may include a plurality of concave portions 141 and a plurality of convex portions 143 which are respectively disposed near or between the plurality of concave portions 141. The convex portion 143 and the concave portion 141 may be connected with each other and alternately arranged in plurality. The plurality of concave portions 141 of the light extraction pattern 140 may have a concave shape with respect to the upper surface 170a of the planarization layer 170, but a surface which is convex in a direction toward the substrate 100 may be connected and arranged in plurality in a lens shape.

Each of the plurality of concave portions 141 may have the same height (or depth) with respect to the upper surface 170a of the planarization layer 170, but some of the plurality of concave portions 141 may have different depths.

The convex portion 143 may be formed to surround each of the plurality of concave portions 141. An upper portion of the convex portion 143 may be adjacent to the light emitting device EP and may have a sharp structure and a convex curved shape, so as to increase light extraction efficiency. For example, the top portion of the convex portion 143 may include a dome or bell structure having a convex cross-sectional shape. For example, the convex portions 143 may be defined at boundary portion portions between adjacent light extraction patterns 140. The convex portions 143 may be defined having a point shape as shown in FIG. 2 by the adjacent concave portions 141. While not shown, the convex portions 143 may have a curved shape so that the adjacent light extraction patterns 140 have a surface with a wave shape.

The convex portion 143 may include an inclined portion having a curved shape between a bottom portion and the top portion (or peak portion). The inclined portion of the convex portion 143 may form or configure the concave portion 141. For example, the inclined portion of the convex portion 143 may be an inclined surface or a curved portion. The inclined portion of the convex portion 143 according to an example embodiment may have a cross-sectional structure having Gaussian curve. In this case, the inclined portion of the convex portion 143 may have a tangent slope which increases progressively from the bottom portion to the top portion, and then decreases progressively.

The light emitting device EP may be disposed adjacent to the light extraction pattern 140 overlapping the emission region EA. The light extraction pattern 140 may be disposed between the light emitting device EP and the substrate 100. The light emitting device EP may include a first electrode E1, a light emitting layer EL, and a second electrode E2.

The first electrode E1 may be formed at (or over) the planarization layer 170 in the subpixel area SPA. One end of the first electrode E1 which is close to the circuit area CA may be electrically connected to the drain electrode 119d (or the source electrode 119s) of the driving TFT Tdr via an electrode contact hole CH provided at or passing through the planarization layer 170 and the protection layer 130.

As the first electrode E1 is formed (or deposited) over the planarization layer 170 to have a relatively thin thickness, the first electrode E1 may have a surface morphology conforming to a surface morphology of the light extraction pattern 140 including the convex portion 143 and the plurality of concave portions 141. The first electrode E1 may have a cross-sectional structure whose shape is the same as the light extraction pattern 140.

The light emitting layer EL may be formed over the first electrode E1 and may directly contact the first electrode E1. As the light emitting layer EL is formed (or deposited) over the first electrode E1 to have a relatively thick thickness in comparison to the first electrode E1, the light emitting layer EL may have a surface morphology which is different from the surface morphology in each of the plurality of concave portions 141 and the convex portion 143 or the surface morphology of the first electrode E1. For example, the light emitting layer EL may be formed in a non-conformal shape which does not conform to the surface shape (or morphology) of the first electrode E1 by a deposition process, whereby the light emitting layer EL may have a cross-sectional structure whose shape may be different from the first electrode E1. The light emitting layer EL according to an example embodiment has a thickness that gradually increases toward the bottom surface of the convex portion 143 or the concave portion 141.

The light emitting layer EL according to an example embodiment includes two or more organic light emitting layers configured to emit white light. As an example, the light emitting layer EL may include a first organic light emitting layer and a second organic light emitting layer to emit white light by mixing a first light and a second light.

The second electrode E2 may be formed over the light emitting layer EL and may directly contact the light emitting layer EL. The second electrode E2 may be formed (or deposited) over the light emitting layer EL to have a relatively thin thickness compared to the light emitting layer EL. The second electrode E2 may be formed (or deposited) over the light emitting layer EL to have a relatively thin thickness, and thus may have a surface morphology corresponding to the surface morphology of the light emitting layer EL. For example, the second electrode E2 may be formed in a conformal shape corresponding to the surface shape (or morphology) of the light emitting layer EL by a deposition process, whereby the second electrode E2 may have the same cross-sectional structure as the light emitting layer EL and may have a cross-sectional structure whose shape may be different from the light extraction pattern 140.

The second electrode E2 may include a metal material having a high reflectance compared to the first electrode E1 to reflect the incident light emitted from the light emitting layer EL toward the substrate 100. For example, the second electrode E2 may include a single-layered structure or multi-layered structure of any one material selected of aluminum (Al), argentums (Ag), molybdenum (Mo), aurum (Au), magnesium (Mg), calcium (Ca), or barium (Ba), or alloy of two or more materials selected from aluminum (Al), argentums (Ag), molybdenum (Mo), aurum (Au), magnesium (Mg), calcium (Ca), or barium (Ba). The second electrode E2 may be a cathode electrode.

The concave portion 141 or the convex portion 143 of the light extraction pattern 140 changes the traveling path of the light emitted from the light emitting layer EL to a second surface 100b which is the light emitting surface (or light extraction surface) 100b, to thereby increase the external extraction efficiency of the light emitted from the light emitting layer EL.

The organic light emitting display apparatus may further include a bank layer 190. The bank layer 190 may be disposed over the planarization layer 170 to cover an edge portion of the first electrode E1. The bank layer 190 may be formed of an organic material such as benzocyclobutene (BCB)-based resin, acrylic-based resin, polyimide resin, or the like.

The bank layer 190 may include a transparent material or an opaque material. The bank layer 190 may include a photosensitizer including a black pigment. When the bank layer 190 includes an opaque material or a black pigment, the bank layer 190 may be referred to as a black bank layer. In this case, when the bank layer 190 is a black bank layer, the bank layer 190 may function as a light blocking member, between adjacent subpixels SP.

The light extraction pattern 140 may be disposed to be wider than the emission region EA, and thus, the bank layer 190 may be disposed to overlap the light extraction pattern 140. An end (or a boundary line of the bank layer) of the bank layer 190 adjacent to the emission region EA may be disposed to cover an edge portion of an outermost pattern of the light extraction pattern 140.

An encapsulation portion 200 may be disposed between the light emitting device EP and the opposite substrate 300. The encapsulation portion 200 may be formed over substrate 100 to cover the second electrode E2. For example, the encapsulation portion 200 may surround the display area AA. The encapsulation portion 200 may protect the thin film transistor and the light emitting layer EL or the like from external impact and prevent oxygen or/and water (or moisture) and particles from being permeated into the light emitting layer EL.

The encapsulation portion 200 may include a plurality of inorganic encapsulation layer. Furthermore, the encapsulation portion 200 may further include at least one organic encapsulation layer interposed between the plurality of inorganic encapsulation layer. The encapsulation portion 200 according to another example embodiment may further include a filler (or a filling member) surrounding (or completely surrounding) an entire display area AA. In this case, the opposite substrate 300 may be bonded to the substrate 100 by using the filler. The filler may include a getter material that absorbs oxygen or/and water (or moisture).

To describe the light extraction pattern 140 of the organic light emitting display apparatus according to an example embodiment of the present disclosure in detail with reference to FIG. 4, the plurality of concave portions 141 of the light extraction pattern 140 may be arranged at a certain interval along a first direction X and may be arranged at a certain interval along a second direction Y intersecting with the first direction X. The first direction X may be a first lengthwise direction of a substrate or may be a long-side lengthwise direction, a widthwise direction, or a first horizontal direction of the display panel. The second direction Y may be a second lengthwise direction of the substrate or may be a short-side lengthwise direction, a lengthwise direction, a second horizontal direction (or a vertical direction) of the display panel. As such, the first direction X and the second direction Y may be parallel to respective edges of the substrate 100.

According to an example embodiment, the center portion CP of each of the adjacent three concave portions 141 may be aligned to form a triangular shape TS. In addition, center portions CP of six concave portions 141, which are disposed at a periphery of one concave portion 141 or surrounds one concave portion 141, may be connected with one another to two-dimensionally form a hexagonal shape HS. The outer periphery of each of the plurality of concave portions 141 may be disposed or arranged in a honeycomb structure, a hexagonal structure, or a circular structure in two-dimensionally (or in plan view).

The plurality of concave portions of the light extraction pattern 140 may have a rotated structure with respect to the first direction X or/and the second direction Y. For example, the light extraction pattern 140 may have a structure where the plurality of concave portions 141 have rotated about a reference point of an emission region with respect to the first direction X or/and the second direction Y. Throughout this description, the rotated structure of a light extraction pattern 140, or any portion thereof, may be considered to refer to a light extraction pattern 140 which is oriented (or angularly positioned) at an angle, such as at an angle about the reference point, or an angle about a center portion of each of the plurality of concave portions. For instance, throughout this description, a light extraction pattern 140 with a rotated structure may be considered to have an orientation (e.g., a rotational orientation—or angular position—in a plane defined by the first direction X and the second direction Y) about a reference point or a center portion of each of the plurality of concave portions.

According to an example embodiment, when a center portion CP of one concave portion 141 of the plurality of concave portions 141 disposed along the first direction X is disposed or aligned in a first straight line SL1 parallel to the first direction X, a center portion CP of the other concave portion 141 disposed adjacent to the one concave portion 141 may be disposed not to be disposed or aligned in the first straight line SL1 parallel to the first direction X. For example, in the example of FIG. 4, the concave portions do not have a symmetry axis parallel to the first direction X.

In addition, when the center portion CP of one concave portion 141 of the plurality of concave portions 141 disposed along the second direction Y is disposed or aligned in the second straight line SL2 parallel to the second direction Y, the center portion CP of the other concave portion 141 disposed adjacent to the one concave portion 141 may be disposed not to be disposed or aligned in the second straight line SL2 parallel to the second direction Y. For example, in the example of FIG. 4, the concave portions do not have a symmetry axis parallel to the second direction Y.

The plurality of concave portions 141 of the light extraction pattern 140 may be configured to rotate by the rotation angle θ3 which is greater than about 0 degrees and less than about 60 degrees, with respect to the arbitrary reference point within a pixel area. Throughout this description, a rotation angle of a light extraction pattern 140 may be considered to be an orientation (e.g., a rotational orientation—or angular position—in a plane defined by the first direction X and the second direction Y) about a reference point or a center portion of each of the plurality of concave portions. The orientation for each light extraction patterns may be measured with respect to the same reference point or reference direction (e.g., the first direction X or the second direction Y). For example, a rotation angle of the light extraction pattern 140 disposed at each of the plurality of pixels P may be set irregularly or randomly along one or more directions of the first direction X and the second direction Y within a range of the rotation angle θ3 which is greater than about 0 degrees and less than about 60 degrees. Throughout this description, the rotation angle of a plurality of light extraction patterns in each subpixel may be measured about (and/or with respect to) the corresponding portion of each subpixel respectively. The arbitrary reference point may be an arbitrary position within the emission region EA of each of the first to fourth subpixels SP1 to SP4 of each pixel P, or may be a center portion CP of any one of the plurality of concave portions 141.

The plurality of concave portions 141 of the light extraction portion 140 may be configured to rotate (or horizontally rotate) or reversely rotate (or horizontally and reversely rotate) by the predetermined third rotation angle θ3 with respect to the arbitrary reference point.

For example, when the plurality of concave portions 141 are disposed in a honeycomb structure, diagonal center lines DCL1 and DCL2 passing through center portions CP of the plurality of concave portions disposed along diagonal directions DD1 and DD2 between the first direction X and the second direction Y may be respectively inclined from the first straight line SL1 and a second straight line SL2. For example, a first angle θ1 between the diagonal center lines DCL1 and DCL2 and the first straight line SL1 may be about 30 degrees, and a second angle θ2 between the diagonal center lines DCL1 and DCL2 and the second straight line SL2 may be about 60 degrees. When the concave portions 141 of the light extraction pattern 140 rotate at about 60 degrees with respect to the arbitrary reference point, the light extraction pattern 140 may be configured to be equal to a case where the concave portions 141 of the light extraction pattern 140 do not rotate with respect to the arbitrary reference point.

According to an example embodiment, the center portion CP of each of the plurality of concave portions 141 disposed at the first direction X may be positioned or aligned at a first tilt line TL1 intersecting with a first straight line SL1. In addition, the center portion CP of each of the plurality of concave portions 141 disposed at the second direction Y may be positioned or aligned at a second tilt line TL2 intersecting with a second straight line SL2.

The first tilt line TL1 may be inclined from the first straight line SL1 by the rotation angle θ3 which is greater than about 0 degrees and less than about 60 degrees. For example, the rotation angle θ3 between the first tilt line TL1 and the first straight line SL1 and/or a second straight line SL2 may be greater than about 0 degrees and less than about 60 degrees. For example, the first tilt line TL1 may be tilted or inclined from the first straight line SL1 and may pass through the center portions CP of the rotated concave portions 141 and may be a first tilt center line or a first center extension line, and the second tilt line TL2 may be tilted or inclined from the second straight line SL2 and may pass through the center portions CP of the rotated concave portions 141 and may be a second tilt center line or a second center extension line.

When the plurality of concave portions 141 are disposed in a honeycomb structure and rotated with respect to the reference point, a fourth angle θ4 between the diagonal center lines DCL1 and DCL2 and the first tilt line TL1 may be about 30 degrees, and a fifth angle θ5 between the diagonal center lines DCL1 and DCL2 and the second straight line SL2 may be about 60 degrees. For example, a rotation angle θ3 between the first straight line SL1 and the first tilt line TL1 of the concave portions 141 or a rotation angle θ3 between the second straight line SL2 and the second tilt line TL2 of the concave portions 141 may be greater than about 0 degrees and less than about 60 degrees.

According to an embodiment of the present disclosure, a pitch (or a distance) L1 between the plurality of concave portions 141 disposed at each of the plurality of subpixels SP configuring the one pixel may be equal or different from each other. The pitch L1 between the plurality of concave portions 141 may be a distance (or an interval) between the center portions CP of the two adjacent concave portions 141.

As an embodiment, the pitch L1 between the plurality of concave portions 141 respectively disposed at a red subpixel, a green subpixel, a blue subpixel and a white subpixel may be equal or different from each other. For example, the pitch L1 between the plurality of concave portions 141 disposed at the green subpixel may be different from the pitch L1 between the plurality of concave portions 141 disposed at the blue subpixel.

As another embodiment, the pitch L1 between the plurality of concave portions 141 disposed at the white subpixel and/or the green subpixel may be different from the pitch L1 between the plurality of concave portions 141 disposed at the red subpixel and/or the blue subpixel.

As another embodiment, the numbers and/or densities of the plurality of concave portions 141 respectively disposed at the red subpixel, the green subpixel, the blue subpixel and the white subpixel may be equal or different from each other. For example, the numbers and/or density of the plurality of concave portions 141 disposed at the white subpixel and/or the green subpixel may be different from the number and/or density of the plurality of concave portions 141 disposed at the red subpixel and/or the blue subpixel.

The organic light emitting display apparatus according to an example embodiment of the present disclosure may include the light extraction pattern 140 having a structure where the light extraction pattern 140 has rotated (or horizontally rotated) by a predetermined angle with respect to an arbitrary reference point, and thus, external light incident from the outside may be reflected from the inside of the organic light emitting display apparatus and a diffraction pattern caused by constructive interference of reflected light may be offset or minimized by the light extraction patterns 140 having different rotation angles, or destructive interference may be more amplified due to the irregularity or randomness of a rotation angle of the light extraction pattern 140, thereby preventing or minimizing the occurrence of a radial-shaped rainbow pattern (rainbow Mura) of the reflected light.

The organic light emitting display apparatus according to another example embodiment of the present disclosure may decrease or minimize the occurrence of rainbow Mura, and thus, may decrease a reduction in black visibility characteristic caused by the reflection of external light in a non-driving or off state, thereby implementing real black.

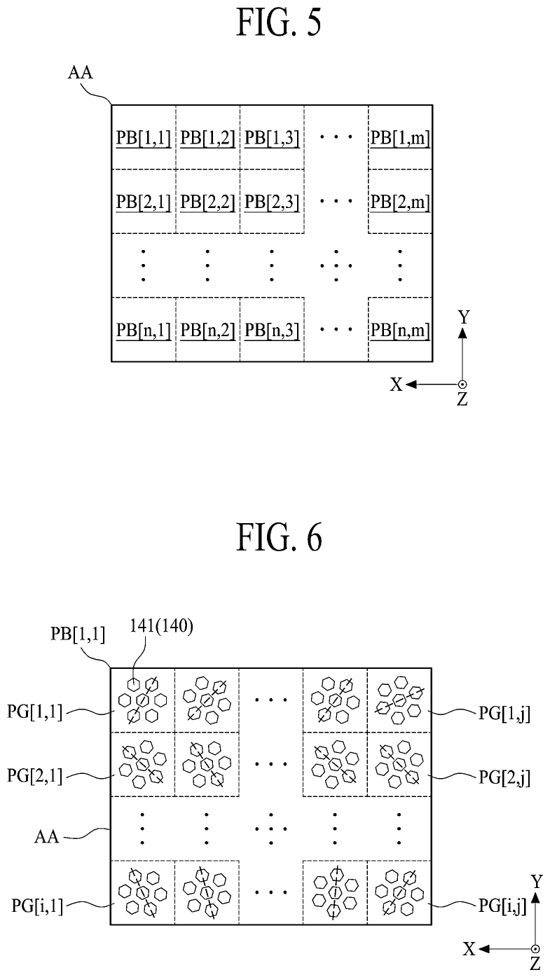

Hereinafter, some embodiments which set a rotation angle of the light extraction pattern 140 within the display area AA will be described. With reference to FIGS. 5 to 7B, a display area AA of an organic light emitting display apparatus may include a plurality of pixel blocks PB[1,1] to PB[n,m].

The display area AA may be divided or blocked into n×m number of pixel blocks PB[1,1] to PB[n,m]. The plurality of pixel blocks PB[1,1] to PB[n,m] may be disposed along n number of rows and m number of columns in the display area AA. A pixel block-based rotation angle of the light extraction pattern 140 disposed in each of the plurality of pixel blocks PB[1,1] to PB[n,m] may be differently disposed by pixel block units, and different angles may be irregularly or randomly set.

For example, the pixel block-based rotation angles of the light extraction pattern 140 disposed at each of pixel blocks directly adjacent to each other along any one direction of the first direction, the second direction, and the diagonal direction among the plurality of pixel blocks PB[1,1] to PB[n,m] may have asymmetry, irregularity, or randomness.

The pixel block-based rotation angles of the light extraction pattern 140 disposed at each of pixel blocks directly adjacent to each other along any one direction of the first direction, the second direction, and the diagonal direction among the plurality of pixel blocks PB[1,1] to PB[n,m] may be differently set to 1 degree or more or 3 degrees or more within a range of 0 degrees or more and less than 60 degrees.

Some of pixel block-based rotation angles of the light extraction patterns 140 disposed at pixel blocks, which are not directly adjacent to each other along any one direction of the first direction, the second direction, and the diagonal direction of the plurality of pixel blocks PB[1,1] to PB[n,m] may be about 0 degrees or equal to one another.

In an example as illustrated in FIG. 6, each of a plurality of pixel blocks PB[1,1] to PB[n,m] may include i×j number (or i number of rows and j number of columns) of pixel groups PG[1,1] to PG[i,j]. For example, each of the plurality of pixel blocks PB[1,1] to PB[n,m] may include 20 pixel groups configured as a 5×4 matrix, but embodiments according to present disclosure are not limited thereto.

Each of the plurality of pixel groups PG[1,1] to PG[i,j] may be configured as one pixel P. For example, the plurality of pixels P disposed at the display area AA may be grouped (or blocked) and may be included in each of the plurality of pixel groups PG[1,1] to PG[i,j].

One or more of the light extraction patterns 140 disposed at a pixel P of each of the plurality of pixel groups PG[1,1] to PG[i,j] may be configured to rotate by a predetermined angle with respect to an arbitrary reference point within a corresponding pixel P. The rotation angles of the light extraction patterns 140 respectively disposed at a plurality of subpixels configuring the one pixel P may be pixel-based rotation angles.

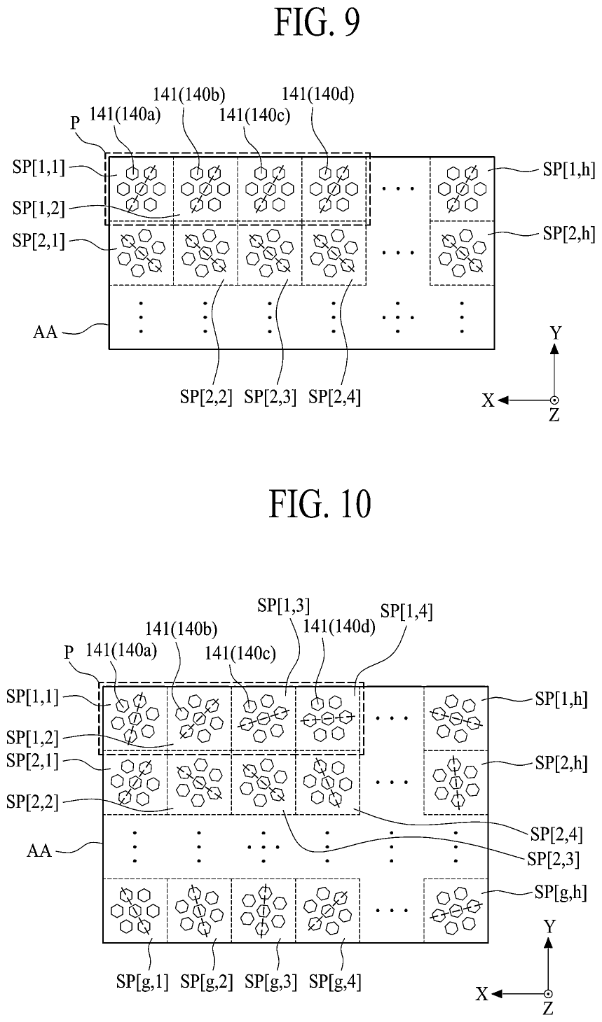

For example, a pixel-based rotation angle of the light extraction pattern 140 may be set to be equal to each of a plurality of subpixels SP configuring one pixel P, and thus, a rotation angle of a pixel P-based light extraction pattern 140 may differ, or rotation angles of the light extraction patterns 140 of a plurality of subpixels SP in the pixel P may be equal to one another (see FIG. 9).

The pixel-based rotation angles of the light extraction patterns 140 disposed at each of the i×j pixel groups PG[1,1] to PG[i,j] included in the pixel block PB[1,1] of 1×1 may have a difference of 1 degree or 3 degrees or more within a range of more than 0 degrees and less than 60 degrees.

For example, the pixel-based rotation angles of the light extraction patterns 140 disposed at one or more pixel groups, which are not adjacent to one another, of the pixel groups PG[1,1] to PG[i,j] included in the pixel block PB[1,1] of 1×1 may be about 0 degrees or may be equal to one another, and pixel-based rotation angles of the light extraction patterns 140 disposed at the other pixel groups (or remaining pixel groups) may be irregularly or randomly set within a range of more than 0 degrees and less than 60 degrees. The pixel-based rotation angles of the light extraction patterns 140 disposed at each of the i×j number of pixel groups PG[1,1] to PG[i,j] corresponding to one pixel block of the pixel blocks PB[1,1] to PB[n,m] may be differently set to 1 degree or more or 3 degrees or more within a range of 0 degrees or more and less than 60 degrees along any one direction of a first direction, a second direction, and a diagonal direction.

The pixel-based rotation angles of the light extraction patterns 140 disposed at each of the i×j number of pixel groups corresponding to one pixel block of the pixel blocks PB[1,1] to PB[n,m] may be set to satisfy the following conditions 1 to 6 within a range of 0 degrees or more and less than 60 degrees.

Condition 1) the pixel-based rotation angles of the light extraction patterns 140 disposed at each of the i×j number of pixel groups PG[1,1] to PG[i,j] may have irregularity or randomness.

Condition 2) the pixel-based rotation angles of the light extraction patterns 140 disposed at each of two pixel groups PG[1,1] to PG[i,j] directly adjacent to each other along any one direction of the first direction, the second direction, and the diagonal direction may have a difference of 1 degree or more or 3 degrees or more.

Condition 3) the pixel-based rotation angles of the light extraction patterns 140 disposed at pixel groups PG[1,1] to PG[i,j] which are not directly adjacent to each other along any one direction of the first direction, the second direction, and the diagonal direction may be about 0 degrees.

Condition 4) two or more adjacent pixel groups PG[1,1] to PG[i,j], where the pixel-based rotation angles of the light extraction patterns 140 have a difference of 1 degree or more or 3 degrees or more, may be disposed between pixel groups PG[1,1] to PG[i,j] where pixel-based rotation angles of the light extraction patterns 140 are about 0 degrees.

Condition 5) the pixel-based rotation angles of the light extraction patterns 140 disposed at pixel groups PG[1,1] to PG[i,j] which are not directly adjacent to each other along any one direction of the first direction, the second direction, and the diagonal direction may be equal to one another.

Condition 6) two or more adjacent pixel groups PG[1,1] to PG[i,j] where the pixel-based rotation angles of the light extraction patterns 140 have a difference of 1 degrees or more or 3 degrees or more may be disposed between pixel groups PG[1,1] to PG[i,j] where pixel-based rotation angles of the light extraction patterns 140 are equal to one another.

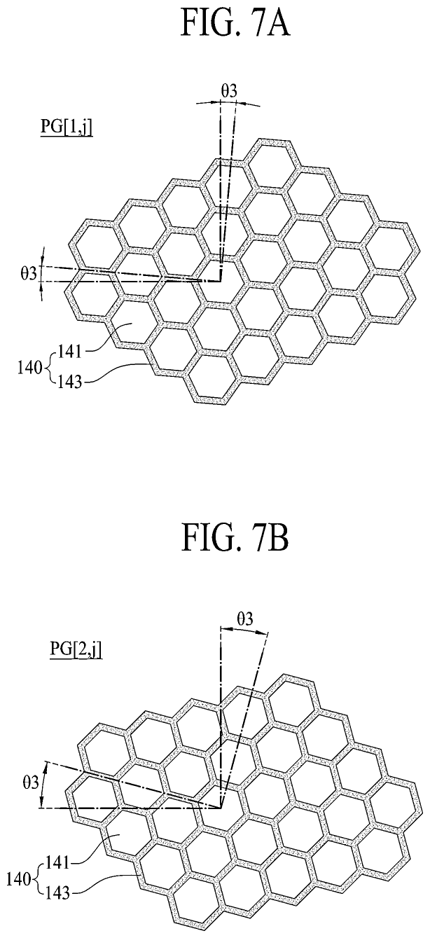

As shown in FIGS. 7A and 7B, in a pixel block PB[1,1] of 1×1 (or 1 row 1 column), a rotation angle θ3 of a light extraction pattern 140 disposed at a pixel block PB[1,j] of 1×j (or 1 row j column) may differ from a rotation angle θ3 of a light extraction pattern 140 disposed at a pixel block PB[2,j] of 2×j (or 2 row j column).

For example, the rotation angle θ3 of the light extraction pattern 140 disposed at the pixel block PB[1,j] of 1×j (or 1 row j column) may have a difference of 1 degree or 3 degrees or more with a rotation angle θ3 of the light extraction pattern 140 disposed at a pixel block PB[2,j] of 2×j (or 2 row j column). For example, the rotation angle θ3 of the light extraction pattern 140 disposed at the pixel block PB[1,j] of 1×j (or 1 row j column) may be about 5 degrees. The rotation angle θ3 of the light extraction pattern 140 disposed at the pixel block PB[2,j] of 2×j (or 2 row j column) may be about 15 degrees.

Therefore, in the organic light emitting display apparatus according to another example embodiment of the present disclosure, a pixel block-based rotation angle of the light extraction pattern 140 disposed in each of the plurality of pixel blocks PB[1,1] to PB[n,m] and a pixel group-based rotation angle of the light extraction pattern 140 disposed in each of the plurality of pixel groups PG[1,1] to PG[i,j] may be differently set, and different rotation angles may be randomly set, thereby offsetting or minimizing a diffraction pattern of reflected light caused by reflected light in the light extraction pattern 140 disposed in each of the plurality of pixels P.

Moreover, according to another example embodiment of the present disclosure, the organic light emitting display apparatus may increase destructive interference due to the irregularity or randomness of the light extraction pattern 140 of each pixel P, and thus, the occurrence of a radial-shaped rainbow pattern and a radial-shaped circular ring pattern of reflected light may be prevented or minimized. Accordingly, a reduction in a black visibility characteristic occurring due to the reflection of external light in a non-driving or turning-off state of the light emitting display apparatus may decrease, and thus, real black may be implemented.

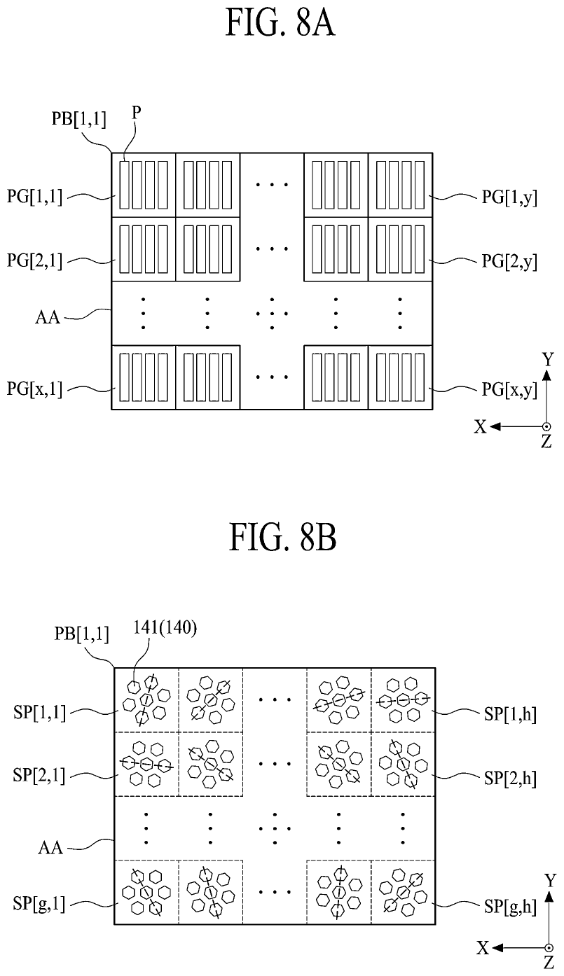

As shown in FIG. 8A, each of a plurality of pixel groups PG[1,1] to PG[x,y] included in one pixel block PB[1,1] may include four or more (or two or more) pixels P. For example, four pixels P adjacent to one another along a first direction X of a plurality of pixels P may be grouped into one pixel group.

According to an example embodiment, in each of the plurality of pixel groups PG[1,1] to PG[x,y], a light extraction pattern 140 disposed in each of four pixels P may have a structure where the light extraction pattern 140 has rotated by a predetermined angle with respect to an arbitrary reference point of a corresponding pixel P. For example, in each of the plurality of pixel groups PG[1,1] to PG[x,y], a light extraction pattern 140 disposed at each of a plurality of subpixels included at each of four pixels P may be configured to rotate by the predetermined angle with respect to a center portion of one concave portion 141 within a corresponding subpixel.

A pixel group-based rotation angle of the light extraction pattern 140 disposed in each of the plurality of pixel groups PG[1,1] to PG[x,y] may be set to be equal to embodiments which set a pixel group-based rotation angle described above with reference to FIGS. 6 to 7B, and thus, repeated descriptions thereof are omitted. For example, the pixel group-based rotation angle of the light extraction pattern 140 disposed in each of the plurality of pixel groups PG[1,1] to PG[x,y] may be applied to the embodiments described above with reference to FIGS. 6 to 7B.

In the organic light emitting display apparatus according to another example embodiment of the present disclosure, a pixel block-based rotation angle of the light extraction pattern 140 disposed in each of the plurality of pixel blocks PB[1,1] to PB[n,m] and a pixel group-based rotation angle of the light extraction pattern 140 disposed in each of the plurality of pixel groups PG[1,1] to PG[i,j] included in each of the plurality of pixel blocks PB[1,1] to PB[n,m] may be differently set, and different rotation angles may be randomly set, thereby offsetting or minimizing a diffraction pattern of reflected light which occurs when external light is input to the inside of the organic light emitting display apparatus and the input light is reflected by the light extraction pattern 140 of each of the plurality of pixels P.

Moreover, according to another example embodiment of the present disclosure, the organic light emitting display apparatus may further increase destructive interference due to the irregularity or randomness of the light extraction pattern 140, and thus, the occurrence of a radial-shaped rainbow pattern and a radial-shaped circular ring pattern may be prevented or minimized. Accordingly, a reduction in a black visibility characteristic occurring due to the reflection of external light in a non-driving or turning-off state of the light emitting display apparatus may decrease, and thus, real black may be implemented.

As illustrated in FIG. 8B, in the organic light emitting display apparatus according to another example embodiment of the present disclosure, one pixel block PB[1,1] may include a plurality of pixel groups PG[1,1] to PG[x,y]. A plurality of subpixels SP may be grouped (or blocked) into g×h number (or g number of rows and h number of columns) of subpixels and may be included in each of the plurality of pixel block PB[1, 1] to PB[n,m].

According to an example embodiment, in each of the plurality of pixel block PB[1,1] to PB[n,m], a light extraction pattern 140 disposed at each of a plurality of subpixels SP may be configured to rotate by a predetermined angle with respect to an arbitrary reference point within a corresponding subpixel. Rotation angles of light extraction patterns 140 respectively provided (or disposed) at each of the g×h number of subpixels SP[1,1] to SP[g,h] included in each of the plurality of pixel block PB[1,1] to PB[n,m] may differ.

For example, the subpixel-based rotation angles of the light extraction patterns 140 provided (or disposed) at each of the g×h number of subpixels SP[1,1] to SP[g,h] included in a pixel block PB[1,1] of 1×1 (or 1 row 1 column) may differ. For example, the subpixel-based rotation angles of light extraction pattern 140 disposed at each of the g×h number of subpixels SP[1,1] to SP[g,h] corresponding to one pixel block of the pixel blocks PB[1,1] to PB[n,m] may have a difference of 1 degree or 3 degrees or more within a range of more than 0 degrees and less than 60 degrees.

For example, the subpixel-based rotation angles of light extraction patterns 140 disposed at each of the g×h number of subpixels SP[1,1] to SP[g,h] included in a pixel block PB[1,1] of 1×1 may have a difference of 1 degree or 3 degrees or more. The subpixel-based rotation angles of light extraction patterns 140 disposed at one or more pixel groups, which are not adjacent to one another, of the g×h number of subpixels SP[1,1] to SP[g,h] included in the pixel block PB[1,1] of 1×1 may be about 0 degrees or may be equal to one another, and subpixel-based rotation angles of the light extraction patterns 140 disposed at the other pixel groups (or remaining pixel groups) may be irregularly or randomly set within a range of more than 0 degrees and less than 60 degrees.

The subpixel-based rotation angles of the light extraction patterns 140 disposed at each of the g×h number of subpixels SP[1,1] to SP[g,h] corresponding to one pixel block of the pixel blocks PB[1,1] to PB[n,m] may be differently set to 1 degree or more or 3 degrees or more within a range of 0 degrees or more and less than 60 degrees along any one direction of a first direction, a second direction, and a diagonal direction.

In the organic light emitting display apparatus according to another example embodiment of the present disclosure, the pixel block-based rotation angles of the light extraction pattern 140 disposed in each of the g×h number of subpixels SP[1, 1] to SP[g,h] included in each of the plurality of pixel blocks PB[1,1] to PB[n,m] and the subpixel-based rotation angles of the light extraction pattern 140 disposed in each of the plurality of subpixels SP[1,1] to SP[g,h] included in each of the plurality of pixel blocks PB[1,1] to PB[n,m] may be differently set, and different rotation angles may be randomly set, thereby offsetting or minimizing a diffraction pattern of reflected light which occurs when external light is input to the inside of the organic light emitting display apparatus and the input light is reflected by the light extraction pattern 140 of each of the plurality of subpixels SP.

Moreover, according to another example embodiment of the present disclosure, the organic light emitting display apparatus may increase destructive interference due to the irregularity or randomness of the light extraction pattern 140 of each subpixel SP, and thus, the occurrence of a radial-shaped rainbow pattern and a radial-shaped circular ring pattern of reflected light may be prevented or minimized. Accordingly, a reduction in a black visibility characteristic occurring due to the reflection of external light in a non-driving or turning-off state of the light emitting display apparatus may decrease, and thus, real black may be implemented.

As shown in FIG. 9, the organic light emitting display apparatus according to another example embodiment of the present disclosure may include g×h number of subpixels SP[1,1] to SP[g,h], four subpixels SP may configure one pixel P, and a light extraction pattern 140 disposed in units of one pixel P may be configured to be rotated by a predetermined angle with respect to an arbitrary reference point of a corresponding pixel P. The light extraction pattern 140 disposed at the one pixel P may rotate by a rotation angle which is greater than about 0 degrees and less than 60 degrees with respect to an arbitrary reference point.

For example, a rotation angle of the light extraction pattern 140 disposed at each of the plurality of pixels P may be set irregularly or randomly along one or more directions of the first direction X and the second direction Y within a range of the rotation angle θ3 which is greater than about 0 degrees and less than about 60 degrees. The arbitrary reference point may be an arbitrary position within a pixel P, or may be a center portion CP of any one of a plurality of concave portions 141.

First to fourth subpixels SP1, SP2, SP3, and SP4 of each pixel P may be configured to rotate (or horizontally rotate) or reversely rotate (or horizontally and reversely rotate) by the predetermined rotation angle with respect to the arbitrary reference point. The light extraction patterns 140 respectively disposed at two adjacent pixels P of the plurality of pixels P may have different rotation angles.

For example, rotation angles of light extraction patterns 140 disposed in first to fourth subpixels SP[1,1] to SP[1,4] of a first row included in one pixel disposed at the first row may be equal to one another and rotation angles of light extraction patterns 140 disposed in first to fourth subpixels SP[2,1] to SP[2,4] of a second row included in one pixel disposed at the second row may be equal to one another, but a rotation angle of a light extraction pattern 140 disposed at one subpixel of the first to fourth subpixels SP[1,1] to SP[1,4] of the first row may differ from a rotation angle of a light extraction pattern 140 disposed at one subpixel of the first to fourth subpixels SP[2,1] to SP[2,4] of the second row or the rotation angles of the light extraction patterns 140 disposed at the first to fourth subpixels SP[2,1] to SP[2,4] of the second row.

According to an example embodiment of the present disclosure, rotation angles of the light extraction patterns 140 respectively disposed at two pixels P adjacent to each other of the plurality of pixels P may have a difference of 1 degree or more. The rotation angles of the light extraction patterns 140 respectively disposed at two pixels P adjacent to each other along one or more directions of the first direction X and the second direction Y may have a difference of 1 degree or more. For example, the light extraction patterns 140 respectively disposed at two pixels P adjacent to each other in all directions may have a difference of 1 degree or more.

For example, the light extraction pattern 140 disposed at an arbitrary pixel P of the plurality of pixels P may be configured in a structure which does not rotate, and the light extraction patterns 140 disposed at another pixel P adjacent to the arbitrary pixel P may be configured to have a rotation angle of 1 degree or more or 3 degrees or more.

Based on a difference between rotation angles of light extraction patterns 140 respectively disposed at adjacent pixels P, radial-shaped rainbow patterns (or diffraction pattern distribution) based on reflected light occurring in each of two adjacent pixels P may be offset or minimized, or based on irregularity or randomness, an offset effect may increase, thereby preventing a rainbow Mura phenomenon. Accordingly, a reduction in a black visibility characteristic occurring due to the reflection of external light in a non-driving or turning-off state of the light emitting display apparatus may decrease, and thus, real black may be implemented.

With reference to FIG. 10, the organic light emitting display apparatus according to another example embodiment of the present disclosure may include g×h number of subpixels SP[1,1] to SP[g,h], a light extraction pattern 140 disposed at each of a plurality of subpixels SP may be configured to rotate by a predetermined angle with respect to an arbitrary reference point within a corresponding subpixel.

Rotation angles of the light extraction patterns 140 respectively disposed at each of the g×h number of subpixels SP[1,1] to SP[g,h] may differ from each other. A rotation angle of a light extraction pattern 140 disposed at each of the plurality of subpixels SP may denote a subpixel-based rotation angle of the light extraction pattern 140.

For example, the subpixel-based rotation angles of the light extraction patterns 140 disposed at each of the g×h number of subpixels SP[1,1] to SP[g,h] may have a difference of 1 degree or 3 degrees or more. The subpixel-based rotation angles of the light extraction patterns 140 disposed at one or more pixel groups, which are not adjacent to one another, of the g×h number of subpixels SP[1,1] to SP[g,h] may be about 0 degrees or may be equal to one another, and subpixel-based rotation angles of the light extraction patterns 140 disposed at the other pixel groups (or remaining pixel groups) may be irregularly or randomly set within a range of more than 0 degrees and less than 60 degrees.

According to an example embodiment, the subpixel-based rotation angles of the light extraction patterns 140 disposed at each of the g×h number of subpixels SP[1,1] to SP[g,h] may be differently set to 1 degree or more or 3 degrees or more within a range of 0 degrees or more and less than 60 degrees along any one direction of a first direction, a second direction, and a diagonal direction.

For example, rotation angles of first to fourth light extraction patterns 140a, 140b, 140c, and 140d respectively disposed at four subpixels SP[1,1] to SP[1,4] may be differently set to 1 degree or more or 3 degrees or more within a range of 0 degrees or more and less than 60 degrees. A rotation angle of a first light extraction pattern 140a configured at a first subpixel SP[1,1] may be about 60 degrees or about 0 degrees where there is no rotation. A rotation angle of a second light extraction pattern 140b configured at a second subpixel SP[1,2] may be about 57 degrees. A rotation angle of a third light extraction pattern 140c configured at a third subpixel SP[1,3] may be about 53 degrees. A rotation angle of a fourth light extraction pattern 140d configured at a fourth subpixel SP[1,4] may be about 49 degrees.

According to another example embodiment, the subpixel-based rotation angles of light extraction patterns 140 disposed at each of the g×h number of subpixels SP[1,1] to SP[g,h] may be set to 0 degrees or more and less than 60 degrees so as to satisfy the conditions 1 to 6.

Condition 1) the subpixel-based rotation angles of the light extraction patterns 140 disposed at each of the g×h number of subpixels SP[1,1] to SP[g,h] may have irregularity or randomness.

Condition 2) the subpixel-based rotation angles of the light extraction patterns 140 disposed at each of two subpixels SP[1,1] to SP[g,h] directly adjacent to each other along any one direction of the first direction, the second direction, and the diagonal direction may have a difference of 1 degree or more or 3 degrees or more.

Condition 3) the subpixel-based rotation angles of the light extraction patterns 140 disposed at subpixels SP[1,1] to SP[g,h] that are not directly adjacent to each other along any one direction of the first direction, the second direction, and the diagonal direction may be about 0 degrees.

Condition 4) two or more adjacent subpixels SP[1,1] to SP[g,h], where the subpixel-based rotation angles of the light extraction patterns 140 have a difference of 1 degree or more or 3 degrees or more, may be disposed between subpixels SP[1,1] to SP[g,h] where subpixel-based rotation angles of the light extraction patterns 140 are about 0 degrees.

Condition 5) the subpixel-based rotation angles of the light extraction patterns 140 disposed at subpixels SP[1,1] to SP[g,h] that are not directly adjacent to each other along any one direction of the first direction, the second direction, and the diagonal direction may be equal to one another.

Condition 6) two or more adjacent subpixels SP[1,1] to SP[g,h] where the subpixel-based rotation angles of the light extraction patterns 140 have a difference of 1 degrees or more or 3 degrees or more may be disposed between subpixels SP[1,1] to SP[g,h] where subpixel-based rotation angles of the light extraction patterns 140 are equal to one another.

According to an example embodiment of the present disclosure, subpixel-based rotation angles of the light extraction patterns 140 disposed at each of the g×h number of subpixels SP[1, 1] to SP[g,h] may be set differently or randomly.

The subpixel-based rotation angles of the light extraction patterns 140 disposed at each of subpixels directly adjacent to each other along any one direction of the first direction, the second direction, and the diagonal direction may have asymmetry, irregularity, or randomness.

Some of subpixel-based rotation angles of the light extraction patterns 140 disposed at each of subpixels, which are not directly adjacent to each other along any one direction of the first direction, the second direction, and the diagonal direction may be about 0 degrees or equal to one another.

Therefore, in the organic light emitting display apparatus according to another example embodiment of the present disclosure, input external light may be reflected from the inside of the organic light emitting display apparatus and a diffraction pattern of reflected light may be offset or minimized by a rotated angle of the light extraction pattern 140 of each of a plurality of subpixels SP, or based on the irregularity or randomness of a rotation angle of each subpixel SP, an effect of destructive interference may more increase, thereby preventing or minimizing the occurrence of a radial-shaped rainbow pattern (rainbow Mura) and a radial-shaped circular ring pattern of reflected light.

The organic light emitting display apparatus according to another example embodiment of the present disclosure may decrease or minimize the occurrence of rainbow Mura, and thus, may decrease a reduction in black visibility characteristic caused by the reflection of external light in a non-driving or off state, thereby implementing real black.

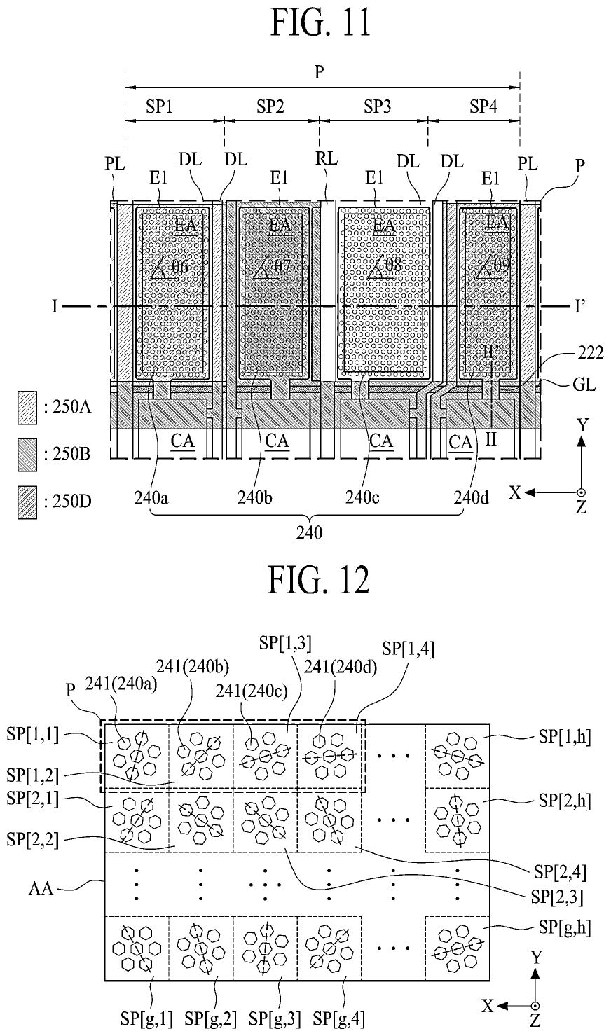

FIG. 11 is a diagram illustrating one pixel in an organic light emitting display apparatus according to another example embodiment of the present disclosure. In the following description, like reference numerals refer to like elements, and repeated descriptions are omitted.

As illustrated in FIG. 11, the organic light emitting display apparatus according to another example embodiment of the present disclosure may include a plurality of subpixels SP1, SP2, SP3, and SP4, each subpixel SP may include a plurality of light extraction patterns 240 (240a, 240b, 240c, and 240d) in an emission region EA defined by a bank layer 290, and rotation angles of the light extraction patterns 240a, 240b, 240c, and 240d of the plurality of subpixels SP1, SP2, SP3, and SP4 may differ. In this case, the different rotation angles of the light extraction patterns 240a, 240b, 240c, and 240d may be randomly set. The light extraction pattern 240 (240a, 240b, 240c, and 240d) may include a plurality of concave portions 241 and a plurality of convex portions 243 which are respectively disposed near or between the plurality of concave portions 241. The convex portion 243 and the concave portion 241 may be connected with each other and alternately arranged in plurality.

For example, adjacent first to fourth subpixels SP1 to SP4 of one pixel P may include a first subpixel SP1, a second subpixel SP2, a third subpixel SP3, and a fourth subpixel SP4, which emit lights of different colors. The first subpixel SP1 may be a red subpixel, the second subpixel SP2 may be a blue subpixel, the third subpixel SP3 may be a white subpixel, and the fourth subpixel SP4 may be a green subpixel. The emission areas EA of each of the first to fourth subpixels SP1, SP2, SP3, and SP4 may have different sizes (or areas) from each other.

Rotation angles θ6, θ7, θ8, and θ9 of the first to fourth light extraction patterns 240a, 240b, 240c, and 240d disposed in the first to fourth subpixels SP1, SP2, SP3, and SP4 may have 3 or more-degree differences within a range of 0 degrees or more and less than 60 degrees. Here, a rotation angle may use, as a criterion, a line which connects center portions of concave portions 241 of the light extraction pattern 240 with one another.

For example, a rotation angle of a first light extraction pattern 240a disposed in the first subpixel SP1 and a rotation angle of a second light extraction pattern 240b disposed in the second subpixel SP2 adjacent thereto may have a three or more-degree difference therebetween. The rotation angle of a second light extraction pattern 240b disposed in the second subpixel SP2 and a rotation angle of a third light extraction pattern 240c disposed in the third subpixel SP3 adjacent thereto may have a three or more-degree difference therebetween, and the rotation angle of the third light extraction pattern 240c disposed in the third subpixel SP3 and a rotation angle of a fourth light extraction pattern 240d disposed in the fourth subpixel SP4 adjacent thereto may have a three or more-degree difference therebetween.

To provide a description, for example, a rotation angle θ6 of a first light extraction pattern 240a configured at a first subpixel SP1 may be about 60 degrees or about 0 degrees where there is no rotation. A rotation angle θ7 of a second light extraction pattern 240b configured at a second subpixel SP2 may be about 57 degrees. A rotation angle θ8 of a third light extraction pattern 240c configured at a third subpixel SP3 may be about 54 degrees or may be about 53 degrees. When the rotation angle θ8 of the third light extraction pattern 240c configured at the third subpixel SP3 is 54 degrees, the rotation angle θ9 of the fourth light extraction pattern 240d configured at the fourth subpixel SP4 may be 51 degrees, or may be 49 degrees. When the rotation angle θ8 of the third light extraction pattern 240c configured at the third subpixel SP3 is 53 degrees, the rotation angle θ9 of the fourth light extraction pattern 240d configured at the fourth subpixel SP4 may be 50 degrees, or may be less than 50 degrees.

An outermost pattern of the plurality of light extraction patterns 240a to 240d disposed in each emission region EA may be disposed up to the outside of the emission region EA and may overlap the bank layer 290. In this case, the outermost pattern may have a rotated angle and may have the same rotation angle as that of the light extraction pattern 240 of the emission region EA of each subpixel SP.

With reference to FIG. 12, light extraction patterns 240 of a plurality of subpixels SP[1,1] to SP[g,h] in a display area AA may be arranged to have three or more-degree differences within a range where a rotation angle between subpixels having the same color is greater than 0 degrees and less than 60 degrees. A rotation angle may use, as a criterion, a line which connects center portions of concave portions 241 of the light extraction pattern 240 with one another.

A subpixel-based rotation angle of the light extraction pattern 240 disposed in each of g×h number of subpixels SP[1,1] to SP[g,h] of the display area AA may be differently set to three degrees or more within a range of 0 degrees or more and less than 60 degrees along one direction of a first direction which is a short-side direction of the display area AA, a second direction which is a long-side direction of the display area AA, and a diagonal direction, and a set angle may have randomness.

For example, when the g×h number of subpixels SP[1,1] to SP[g,h] are disposed in the display area AA and subpixels of the same color are arranged in a column direction, a first subpixel SP[1,1] and a first subpixel SP[g, 1] of a g^{th} row which is a subpixel of the same color may be disposed apart from each other without being adjacent to each other, rotation angles of the first subpixel SP[1,1] and the first subpixel SP[g, 1] of the g^{th} row may be set to have a three or more-degree difference within a range of 0 degrees or more and less than 60 degrees, and a set rotation angle may have randomness.

A rotation angle of the light extraction pattern 240 may be applied based on a combination of settings of rotation angles of light extraction patterns in the display area AA in the other embodiments described above with reference to FIGS. 5 to 10.

Therefore, in the organic light emitting display apparatus according to another example embodiment of the present disclosure, input external light may be reflected from the inside of the organic light emitting display apparatus and a diffraction pattern of reflected light may be offset or minimized by a rotated angle of the light extraction pattern 140 of each of a plurality of subpixels SP, or based on the irregularity or randomness of a rotation angle of each subpixel SP, an effect of destructive interference may more increase, thereby preventing or minimizing the occurrence of a radial-shaped rainbow pattern (rainbow Mura) and a radial-shaped circular ring pattern of reflected light. The organic light emitting display apparatus according to another example embodiment of the present disclosure may decrease or minimize the occurrence of rainbow Mura, and thus, may decrease a reduction in black visibility characteristic caused by the reflection of external light in a non-driving or off state, thereby implementing real black.

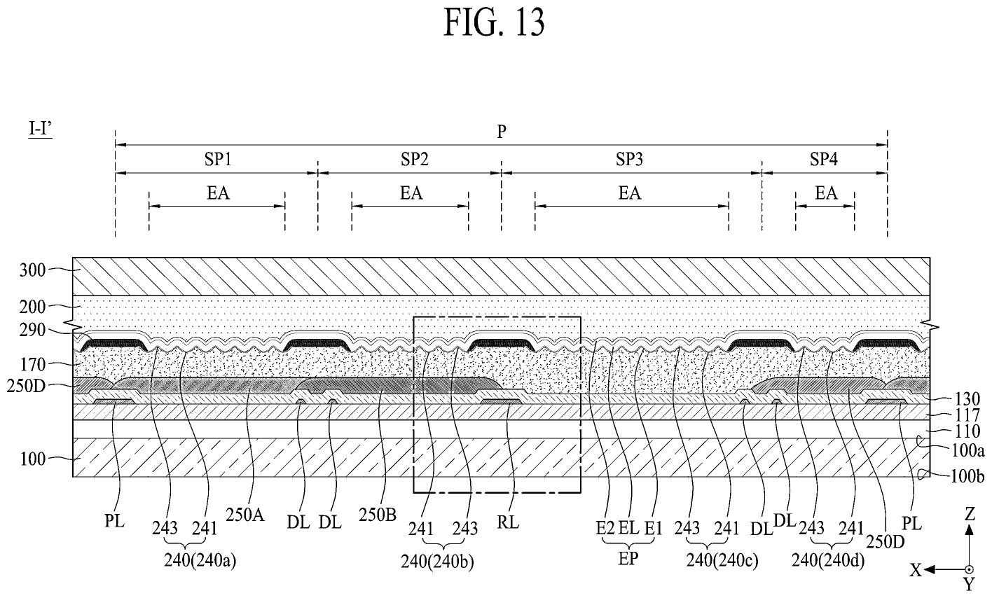

A color filter layer 250 disposed between the light extraction pattern 240 and the substrate 100 may have a size which is wider than that of the emission region EA as illustrated in FIGS. 11 and 13. A color filter layer 250 may have a region having a size which is wider than that of a region of a plurality of light extraction patterns 240 in each subpixel SP except a white subpixel. When the color filter layer 250 has a size which is wider than that of the light extraction pattern 240, the occurrence of light leakage where internal light is leaked to an adjacent subpixel SP may be reduced.

The color filter layer 250 may extend up to a portion of a circuit region CA and may be disposed to overlap a first electrode E1 connected with the circuit region CA. A color filter layer 250 corresponding to one subpixel SP may be disposed to extend up to a portion of a circuit region CA of the other subpixel SP adjacent or neighbor thereto.

For example, when the first subpixel SP1 is a red subpixel, the second subpixel SP2 is a blue subpixel, the third subpixel SP3 is a white subpixel, and the fourth subpixel SP4 is a green subpixel, a second color filter layer 250B corresponding to a blue second subpixel SP2 may be disposed up to a portion of a circuit region CA of the second subpixel SP2 to overlap a connection portion 222 of a first electrode E1 disposed between an emission region EA and the circuit region CA of the second subpixel SP2 and may be disposed up to a portion of a circuit region CA of each of the third and fourth subpixels SP3 and SP4 to overlap a connection portion 222 of a first electrode E1 disposed between an emission region EA and the circuit region CA of each of the third and fourth subpixels SP3 and SP4. The second color filter layer 250B corresponding to the blue second subpixel SP2 may be disposed up to a portion of a circuit region CA of the first subpixel SP1 to overlap a connection portion 222 of a first electrode E1 disposed between an emission region EA and the circuit region CA of the first subpixel SP1.

As another example embodiment, the first color filter layer 250A corresponding to the red first subpixel SP1 may be disposed up to a portion of a circuit region CA of the first subpixel SP1 to overlap a connection portion 222 of a first electrode E1 disposed between an emission region EA and the circuit region CA of the first subpixel SP1.

As another embodiment, the third color filter layer 250D corresponding to the green fourth subpixel SP4 may be disposed up to a portion of a circuit region CA of the fourth subpixel SP4 to overlap a connection portion 222 of a first electrode E1 disposed between an emission region EA and the circuit region CA of the fourth subpixel SP4.

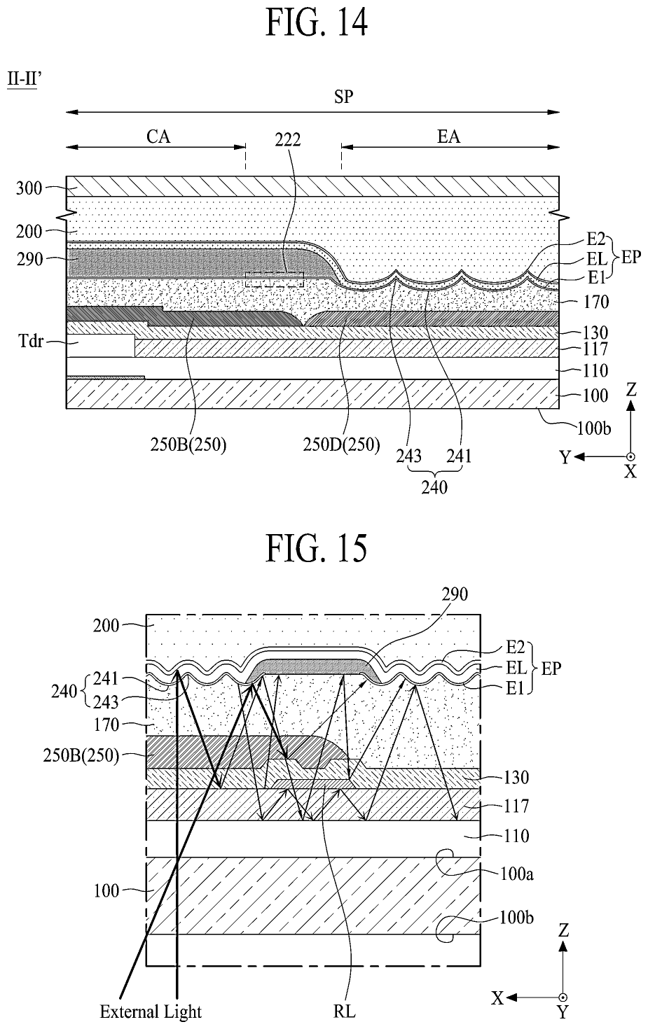

In FIGS. 11, 13, and 14, in a case where a color filter layer 250 is disposed to overlap a connection portion 222 of a first electrode E1 disposed between an emission region EA and a circuit region CA, the connection portion 222 of the first electrode E1 may be used as a repair portion, and thus, when a hot or dark spot occurs, a subpixel SP may be repaired, thereby enhancing the reliability of driving. For example, the connection portion 222 of the first electrode E1 which is electrically connected to the driving TFT Tdr may be used as the repair portion.

In a case where a blue color filter layer 250B is disposed to overlap a connection portion 222 of a first electrode E1 disposed between an emission region EA and a circuit region CA of another neighboring or adjacent subpixel SP, when laser repair is applied, the blue color filter layer 250B having a relatively short wavelength may block a laser beam having a relatively long wavelength, thereby preventing or minimizing the damage of peripheral layers caused by a laser beam in performing repair.

The bank layer 290 defining an emission region EA may be disposed between emission regions EA of light extraction patterns 240 having a rotated structure to cover an edge of the first electrode E1. The bank layer 290 may be disposed to overlap a plurality of lines PL, DL, and RL thereunder, between the emission regions EA.

The bank layer 290 may include an opaque material or a photosensitizer including a black pigment. The bank layer 290 may be formed of an organic material such as benzocyclobutene (BCB)-based resin, acrylic-based resin, polyimide resin, or the like. When the bank layer 290 includes an opaque material or a black pigment, the bank layer 290 may be referred to as a black bank layer. When the bank layer 290 is a black bank layer, the bank layer 290 may function as a light blocking member between emission regions EA of an adjacent subpixel SP and may prevent or minimize the reflection of internally scattered light to an adjacent or neighboring subpixel SP.

In a case where the bank layer 290 is disposed as the black bank layer between adjacent emission regions EA, the bank layer 290 may block an internal light path, and thus, it may not be needed to place a separate light blocking structure between adjacent emission regions EA, thereby decreasing the occurrence of a step height of stacked layers.

Therefore, in the organic light emitting display apparatus according to another example embodiment of the present disclosure, because the bank layer 290 is disposed as the black bank layer between emission regions EA, a boundary of the emission regions EA may increase or enlarge, thereby enhancing an aperture ratio.

The bank layer 290 may be the black bank layer and may be disposed to overlap the connection portion 222 of the first electrode E1 connecting an emission region EA with a circuit region CA of one subpixel SP, between the emission region EA and the circuit region CA of the one subpixel SP. In this case, in a case where the connection portion 222 is applied as a repair portion, the bank layer 290 to which the black bank layer is applied may minimize the damage of a light emitting device EP in performing laser repair.

The bank layer 290 may be the black bank layer and may be disposed to overlap an outermost light extraction pattern 240 of light extraction patterns 240 having a rotated structure. The outermost light extraction pattern 240 may also have a rotated structure. The bank layer 290 may be the black bank layer and may be disposed between light extraction patterns 240 having different rotation angles for each of adjacent subpixels SP.

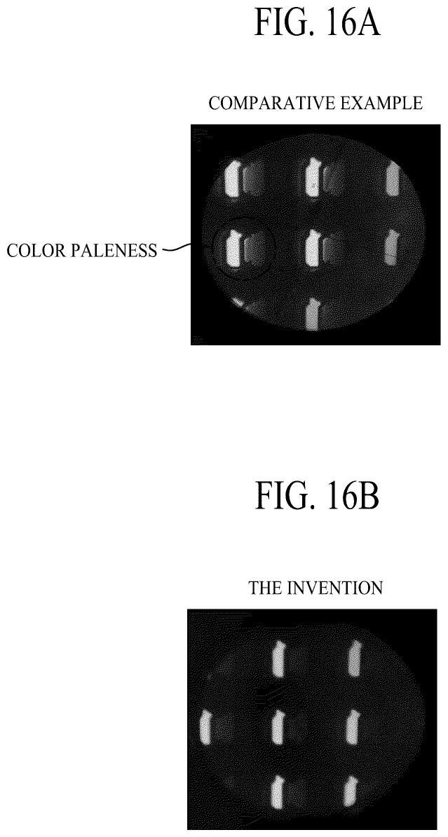

Various internal lights of a display apparatus, as illustrated in FIG. 15, may occur through various scattering angles, and for example, external light may be input to the inside of the substrate 100 and thus reflected light by the concave portions 241 and the convex portions 243 of the light extraction pattern 240 may occur and may occur based on a refractive index difference of various layers (for example, 110, 117, 130, 250, and 170) thereof. The movement of lights, generated through various scattering angles, to adjacent subpixels by the bank layer 290 which is the black bank layer disposed between light extraction patterns 240 having a rotated structure may be reduced, and thus, the organic light emitting display apparatus according to the present disclosure may prevent or reduce a color paleness phenomenon (see FIG. 16A) and may improve image quality as in a photograph of FIG. 16B.

The color paleness phenomenon may better occur due to the movement of light to an adjacent subpixel where the color filter layer 250 is not disposed. In the organic light emitting display apparatus according to another example embodiment of the present disclosure, as illustrated in FIGS. 13 and 15, the bank layer 290 which is the black bank layer may be disposed between a subpixel (for example, SP3) where the color filter layer 250 is not disposed and a subpixel (for example, SP2) where the color filter layer 250 is disposed, and thus, reflected lights may be absorbed by the bank layer 290 which is the black bank layer or the amount of reflection of reflected lights may decrease to minimize or prevent the movement of lights to the subpixel (for example, SP3) where the color filter layer 250 is not disposed, thereby decreasing the color paleness phenomenon.

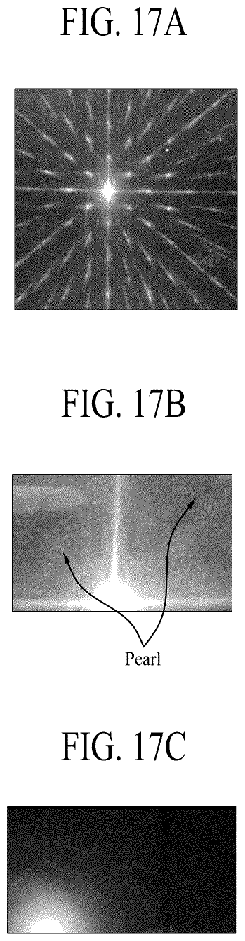

The light extraction pattern 240 which is disposed in the emission region EA and has a rotated structure, as described above, may have irregularity or randomness, and thus, may offset or minimize constructive interference where light concentrates, thereby preventing rainbow Mura (see FIG. 17A). In the organic light emitting display apparatus according to another example embodiment of the present disclosure, the bank layer 290 may be disposed as the black bank layer between emission regions EA of light extraction patterns 240 having a rotated structure, and thus, the concentration of light may be prevented or more minimized, thereby preventing a pearl phenomenon (seen FIG. 17B) where several portions are whitely seen due to the multi-interference of various scattered lights.

Therefore, in the organic light emitting display apparatus according to another example embodiment of the present disclosure, the bank layer 290 may be disposed as the black bank layer between emission regions EA including the light extraction pattern 240 having a rotated structure, and thus, may prevent the movement of light to an adjacent subpixel SP or emission region EA, thereby enhancing an aperture ratio or decreasing a color paleness phenomenon.

Moreover, in the organic light emitting display apparatus according to another example embodiment of the present disclosure, because the bank layer 290 may be disposed as the black bank layer between emission regions EA including the light extraction pattern 240 having an irregularly rotated structure, various scattered lights occurring through various paths such as internal reflection of external light input to the inside and reflection based on a refractive index difference of internal light may prevent concentration caused by constructive interference or may be offset, and multi-interference may be minimized, thereby preventing a phenomenon such as rainbow Mura and may preventing a speckle phenomenon and a pearl phenomenon as in a photograph of FIG. 17C.

In the organic light emitting display apparatus according to an example embodiment of the present disclosure, light extraction efficiency may be enhanced and reflected lights may be offset, and thus, the occurrence of a radial-shaped rainbow pattern and a radial-shaped circular ring pattern of reflected light may be prevented or minimized, whereby it may be seen that a black visibility characteristic is enhanced. Accordingly, the organic light emitting display apparatus according to the present disclosure may implement high efficiency and high luminance, extend a lifetime of a light emitting device (or an organic light emitting device), and decrease power consumption, thereby implementing low power.

An organic light emitting display apparatus according to the present disclosure may improve reflection visibility caused by reflected light reflected from the inside and an input of external light and may prevent black color (or black rising), thereby implementing real black in a non-driving or off state.

An organic light emitting display apparatus according to the present disclosure may irregularly or randomly rotate a light extraction pattern, and thus, may decrease rainbow Mura.

An organic light emitting display apparatus according to the present disclosure may apply, as a black bank layer, a bank layer disposed between light extraction patterns having a rotated structure to block or improve paths of various scattered light caused by an input of external light and reflection from the inside or/and various paths, and thus, may enhance an aperture ratio and may improve a color paleness phenomenon occurring through various scatter angles.

An organic light emitting display apparatus according to the present disclosure may apply, as a black bank layer, a bank layer disposed between light extraction patterns having an irregularly or randomly rotated structure to prevent the occurrence of a speckle phenomenon and a pearl phenomenon.

The above-described feature, structure, and effect of the present disclosure are included in at least one embodiment of the present disclosure, but are not limited to only one embodiment. Furthermore, the feature, structure, and effect described in at least one embodiment of the present disclosure may be implemented through combination or modification of other embodiments by those skilled in the art. Therefore, content associated with the combination and modification should be construed as being within the scope of the present disclosure.

It will be apparent to those skilled in the art that various modifications and variations can be made in the organic light emitting display apparatus of the present disclosure without departing from the spirit or scope of the disclosure. Thus, it is intended that the present disclosure cover the modifications and variations of this disclosure provided they come within the scope of the appended claims and their equivalents.

What is claimed is:

1. An organic light emitting display apparatus, comprising:
a plurality of subpixels in an emission region; and
a planarization layer in the plurality of subpixels, the planarization layer including a plurality of light extraction patterns including a convex portion and a plurality of concave portions,
wherein at least a first light extraction pattern of the plurality of light extraction patterns is rotated with respect to a center portion of each of the plurality of concave portions.

2. The organic light emitting display apparatus of claim 1, wherein a shape of the light extraction patterns in each of the plurality of subpixels have a respective rotation angle that is different for each of the plurality of subpixels.

3. The organic light emitting display apparatus of claim 1, wherein rotation angles of light extraction patterns disposed in two adjacent subpixels of the plurality of subpixels have a three or more-degree difference within a range of more than 0 degrees and less than 60 degrees.

4. The organic light emitting display apparatus of claim 1, wherein rotation angles of light extraction patterns disposed in subpixels of the same color among light extraction patterns respectively disposed in the plurality of subpixels have a three or more-degree difference within a range of more than 0 degrees and less than 60 degrees.

5. The organic light emitting display apparatus of claim 1, wherein rotation angles of light extraction patterns disposed in two subpixels adjacent to each other in a first direction, a second direction perpendicular to the first direction, or a diagonal direction among the plurality of subpixels have a three or more-degree difference within a range of more than 0 degrees and less than 60 degrees.

6. The organic light emitting display apparatus of claim 1, further comprising:
a substrate on which the plurality of subpixels are disposed;
a plurality of color filter layers each disposed to correspond to a corresponding subpixel, the color filter layers being between the substrate and the planarization layer; and
a bank layer defining the emission region of each of the plurality of subpixels,
wherein each color filter layer is disposed to extend from the emission region up to a circuit region of the corresponding subpixel.

7. The organic light emitting display apparatus of claim 6, wherein the plurality of subpixels includes first, second, third, and fourth subpixels, and
wherein a color filter layer disposed in a subpixel emitting light of a color having a shortest wavelength among the first to fourth subpixels is disposed to extend up to the circuit region of an adjacent subpixel of a different color.

8. The organic light emitting display apparatus of claim 7, wherein the first subpixel is a red subpixel, the second subpixel is a blue subpixel, the third subpixel is a white subpixel, and the fourth subpixel is a green subpixel, and
wherein the second subpixel is disposed to extend up to circuit regions of the third and fourth subpixels.

9. The organic light emitting display apparatus of claim 1, further comprising:
a substrate where the plurality of subpixels are disposed;
a color filter layer disposed to correspond to a corresponding subpixel, the color filter layer being between the substrate and the planarization layer; and
a light emitting device including a first electrode, a light emitting layer, and a second electrode each disposed in a respective one of the plurality of subpixels,
wherein the first electrode of each of the subpixels is disposed in the emission region of each respective subpixel,
wherein, for each of the subpixels, the first electrode includes a connection portion disposed between the emission region and a circuit region outside the emission region, and
wherein the color filter layer disposed to correspond to the corresponding subpixel overlaps the connection portion.

10. The organic light emitting display apparatus of claim 9, wherein the plurality of subpixels includes first, second, third, and fourth subpixels, and
wherein the color filter layer disposed in a subpixel emitting light of a color having a shortest wavelength among the first to fourth subpixels is disposed to extend up to the connection portion of an adjacent subpixel of a different color and overlap the connection portion.

11. The organic light emitting display apparatus of claim 10, wherein the first subpixel is a red subpixel, the second subpixel is a blue subpixel, the third subpixel is a white subpixel, and the fourth subpixel is a green subpixel, and
wherein the second subpixel is disposed to overlap the connection portion of the third and fourth subpixels.

12. The organic light emitting display apparatus of claim 11, wherein the second subpixel is disposed to extend up to circuit regions of the third and fourth subpixels.

13. The organic light emitting display apparatus of claim 6, wherein the bank layer includes a black pigment.

14. The organic light emitting display apparatus of claim 6, wherein the bank layer is a black bank layer and overlaps an outermost pattern having a rotated structure of the light extraction pattern.

15. The organic light emitting display apparatus of claim 6, wherein the bank layer is a black bank layer and is disposed between light extraction patterns having different rotation angles for each of adjacent subpixels.

16. The organic light emitting display apparatus of claim 6, further comprising a light emitting device including a first electrode, a light emitting layer, and a second electrode each disposed in each of the plurality of subpixels,
wherein the bank layer is a black bank layer,
wherein the first electrode comprises the emission region of a corresponding subpixel and a connection portion connecting the emission region with the circuit region, and
wherein the black bank layer is disposed to overlap the connection portion.

17. An organic light emitting display apparatus, comprising:
a substrate having edges defined parallel to a first direction and a second direction;
a plurality of subpixels in an emission region defined on the substrate; and
a planarization layer in the plurality of subpixels, the planarization layer including a plurality of light extraction patterns including a plurality of concave portions in each subpixel,
wherein a direction between centers of any adjacent ones of the light extraction patterns is not parallel to the first direction or the second direction.

18. The organic light emitting display apparatus of claim 17, wherein the direction between centers is different for each of the plurality of subpixels.

19. An organic light emitting display apparatus, comprising:
a substrate having edges defined parallel to a first direction and a second direction;
a plurality of subpixels in an emission region defined on the substrate; and
a planarization layer in the plurality of subpixels, the planarization layer including a plurality of light extraction patterns including a plurality of concave portions in each subpixel,
wherein each one of the light extraction patterns has a shape defining one or more symmetry axis, the one or more symmetry axis being rotated with respect to the first and second directions to define an angle with respect to the first and second directions.

20. An organic light emitting display apparatus, comprising:
a substrate having a plurality of subpixels defined in an emission region of the substrate;
a planarization layer on the substrate in the plurality of subpixels, the planarization layer having an upper surface including a plurality of concave portions in each subpixel, and
a light emitting device in each of the plurality of plurality of subpixels, each light emitting device being on the concave portions of the respective subpixel and having a shape conforming to the respective concave portions.
